(19) United States
(12) Patent Application Publication
(10) Pub. No.: US 2005/0280100 A1
(43) Pub. Date: Dec. 22, 2005

(54) Laterally diffused MOS device

(76) Inventors: Michael Artaki, Furlong, PA (US); Isik C. Kizilyalli, Allentown, PA (US); Zhijian Xie, Allentown, PA (US)

Correspondence Address: Mr. Bruce S. Schneider, 1153 Long Hill Road, Stirling, NJ, 07980-1007, US

(21) Appl. No.: 10/870,102

(22) Filed: Jun. 17, 2004

(51) Int. Cl. H01L 29/76

(52) U.S. Cl. 257/382

(57) ABSTRACT

Significant improvement in gain is achievable in a laterally diffused MOS device without substantial change in threshold voltage. Such improvement in a device having a channel with lateral dopant gradient of at least a factor of 10 per micrometer of channel is attained using a P-type gate. For example, a gₘ of 0.02 S/mm (at VDS=28 V) and a drain breakdown of more than 70V with gate oxide of 350 Å is possible with a threshold voltage of 3.5 volts.

### TECHNICAL FIELD

This invention relates to field effect transistor devices and in particular such devices having laterally diffused channels.

### BACKGROUND OF THE INVENTION

Laterally diffused metal oxide semiconductor (MOS) devices have seen widespread use in discrete and integrated circuit high voltage applications. Such devices differ from typical integrated circuits used for memory and logic applications in the method of forming the channel and the presence of relatively large distances between the drain contact and the channel region (drift region) and thick gate dielectrics. Such differences are employed to accommodate the intended high input and output voltages. For example 65 to 75 V technologies utilize 200 to 500 Å gate dielectrics and drift regions that extend 2 to 3 μm, while 10 to 15V technologies use a gate oxide thickness of 80 to 200 Å and drift regions of 0.5 to 2 μm.

In their formation, a gate dielectric, e.g. oxide, 3 in FIG. 1, is generally first formed (step 70) by thermal oxidation on the surface of a substrate e.g. a silicon substrate, 1. A polysilicon region, 6, is then formed on the gate oxide by deposition of polysilicon, photolithographic definition of the gate electrode region, followed by removal, except in the gate electrode region, 6, of the polysilicon layer through etching. The source side of the gate is then masked (step 80) using a photoresist material, 7 in FIG. 1. Using this mask, an LDD region is formed by implantation of an N-type dopant such as arsenic or phosphorus to produce region 9. (This LDD region is typically denominated LDD1). After removal of the photoresist, 7, another photoresist region, 8, is formed (step 90) and a P+ implanted region, 2, is produced using a dopant species such as boron. After removal of the photoresist region 8, the drain region is masked using photoresist 10, (step 100) and the second implant of a P-type dopant such as boron is employed to produce region 11. The photoresist is then removed. Another region of photoresist, 13, (step 110) is applied to mask the source region and the LDD 1 region. The exposed drain region is then implanted with a N-type dopant such as arsenic or phosphorus to produce LDD 2 region, 15. The dopant present in region 11 is induced (step 120) to diffuse under the gate by a thermal drive. As a result, after removal of the photoresist region 13, the device has P-type channel region 12 underlying gate 6 with drain regions 9 and 15. A source contact is formed in the source region adjacent gate 6, and a drain contact (N⁺region) is formed in the drain region at a position removed from gate 6 such as at region 16 (step 130). Conventional techniques such as implantation and diffusion are employed for such formation. The gate is completed by N-type doping of polysilicon region 6 or by formation of a silicide such as titanium silicide with N-type doping of the underlying polysilicon region. Such doping and silicide formation are accomplished by conventional techniques such as metal deposition and thermal inducement of silicide formation.

The formation sequence in these high voltage devices leads to a notable characteristic. As discussed above, the channel—the P-type conductive region delimited by the edges of the gate and underlying the gate—is formed by lateral diffusion from the source region side of the gate region. Thus the dopant concentration is greatest at the source side of the channel delimited by imaginary dotted line 20 in FIG. 2 and decreases to its other boundary 21 in FIG. 2. (The drain side boundary is that extending from the drain side of the gate downward into the substrate at an angle perpendicular to the major surface of the substrate at the gate oxide level.) This dopant profile for the channel is significantly different from that generally found in integrated circuits (ICs) based on field effect transistors. For memory and logic ICs, the field effect transistor channel doping is typically established by ion implantation uniformly in the channel and thus the dopant concentration laterally under the gate is essentially constant. (However because of the characteristics of ion implantation, the dopant concentration in logic ICs does vary in the direction perpendicular to the major surface of the substrate.) In any laterally diffused MOS device both the channel doping profile and the threshold voltage of the device significantly affect operation. The resulting power gain of the device is primarily determined by the transconductance of the channel. (Transconductance is defined as the derivative of channel current with respect to gate voltage.) As discussed, one significant factor affecting transconductance is the dopant concentration of the channel. As the doping level in the channel increases, the transconductance decreases since electron mobility decreases due to ionized impurity scattering. Thus, the greater the dopant concentration, the smaller the transconductance from the source to the drain. As a result, from the perspective of desiring a high transconductance (and thus a high power gain), it is desirable to have a correspondingly low dopant concentration profile in the channel. However, lowering the dopant profile reduces the threshold voltage and, in turn, there is a greater tendency for channel punch through and negative gate voltage at high input power. (Threshold voltage is the minimum gate voltage required to allow current flow greater than 1 nA/μm of gate width between source and drain.) Thus in laterally diffused MOS devices, there is a trade off between power gain (or transconductance) versus threshold voltage. This trade off has generally limited transconductance gain to less than 0.02 S/mm (at V_{DS}=28 V) for typical device threshold voltages of 3.5 volts, breakdown voltage of more than 70 volts and gate oxide thickness of 350 Å. Any expedient that mitigates the extent of this trade off is quite significant.

### SUMMARY OF THE INVENTION

It has been found that devices having a lateral dopant concentration gradient in the channel across the gate greater than a factor of 10 per micrometer of channel length, preferably a factor of 20 per micrometer of channel length, are significantly improved by the use of a gate electrode whose majority carrier is holes. By the use of a P-type gate electrode with a channel having a suitable dopant gradient the needed trade off between transconductance (power gain) and threshold voltage is substantially diminished. In particular, the transconductance improves as much as 25 percent (over an N+ gate electrode device) while the voltage threshold is maintained at nominal levels such as 3.5 volts. Channel punch-through in devices having a suitable gradient and P-type gate electrode is not significant up to a drain voltage of 100 volts. The inventive devices are producible using essentially the same fabrication sequence as in prior devices. However, the gate electrode rather than being N doped is instead P doped. Thus the improvements associated with a P-type electrode gate in a device having suitable channel dopant gradient is achievable without modifying conventional manufacturing techniques.

### BRIEF DESCRIPTION OF THE DRAWINGS

FIG. 1 is illustrative of fabrication steps in laterally diffused MOS devices;

FIG. 2 demonstrates concepts relating to the device channel; and

FIG. 3 illustrates properties achievable in one embodiment of the invention.

### DETAILED DESCRIPTION

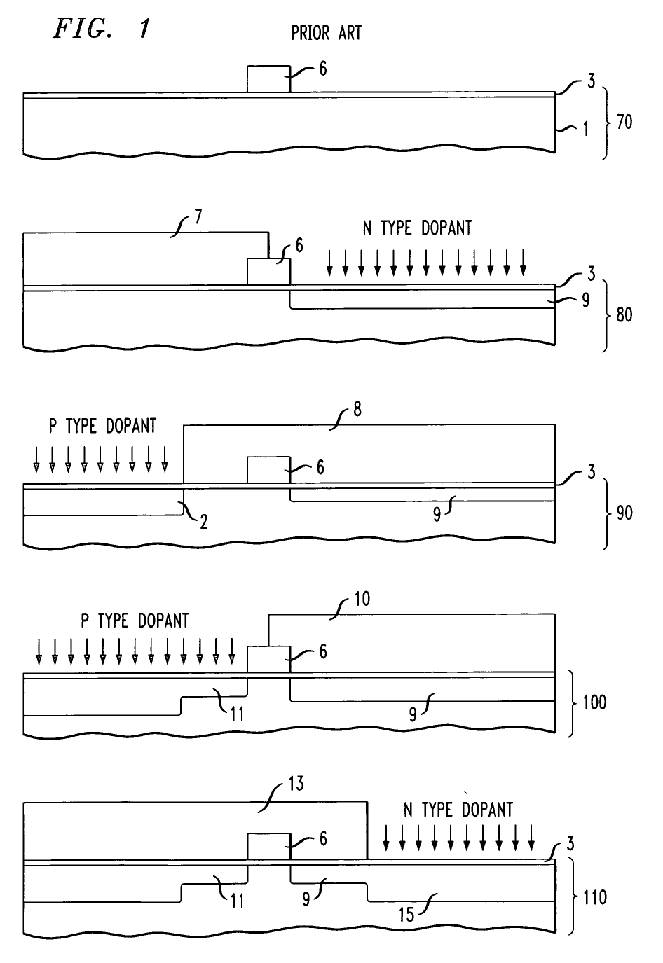

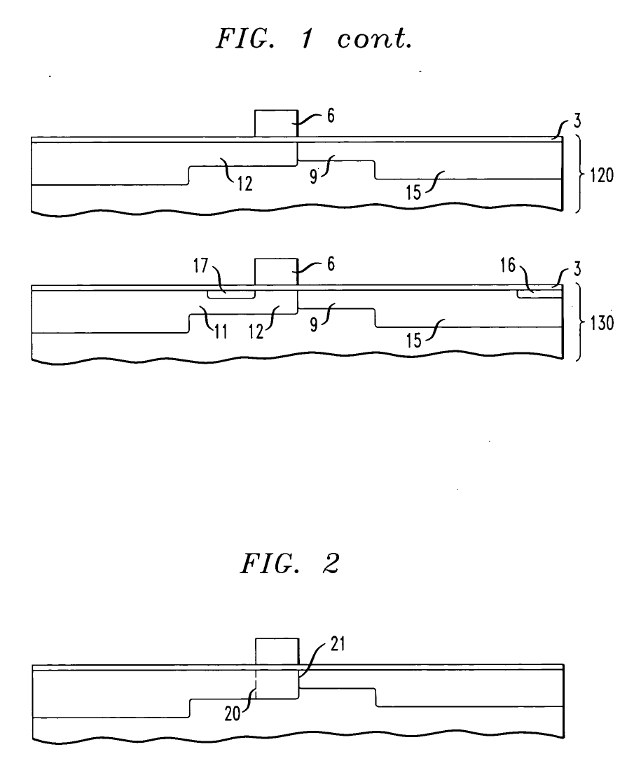

As discussed the subject invention resides in the use of a P-type gate electrode in a device also having a lateral channel dopant concentration gradient greater than a factor of 10 per micrometer of channel length. That is, the P-type dopant concentration in the channel to a depth of 0.1 μm at the gate boundary of the device on the source side is at least a factor of 10, preferably a factor of 20, greater than the concentration to a corresponding depth at the gate boundary on the drain side of the gate per micrometer of channel length between these two boundaries. Thus as shown in FIG. 2, the P-type dopant concentration at 20 is at least 10 times greater than the P-type dopant concentration at 21 if the channel distance between 20 and 21 is 1 μm and 20 times greater if the distance is 2 μm. In a device fabrication sequence shown in FIG. 1 the channel gradients of the inventive devices are generally produced by implanting region 11 with a P-type dopant dose in the range 2×10¹³ to 5×10¹⁴ cm⁻². This dopant concentration level is then induced to diffuse under the gate using a thermal drive in the range 900° C. to 1200° C. for a time 10 to 100 minutes. Alternatively, it is possible to use rapid thermal anneal to induce the desired lateral diffusion. Typically, this anneal is performed for a time period in the range 1 to 10 minutes to induce the desired diffusion. Generally the P-type region 11 is formed by implantation of boron. Suitable implant doses in the range 1×10¹² to 1×10¹⁵ atoms/cm² are employed with an implant acceleration voltage in the range 10 keV to 200 keV. To ensure implantation in the desired region typically the masking photoresist 10 in step 100 of FIG. 1 has a thickness in the range 1 μm to 10 μm.

The gate electrode 6 in FIG. 1 is typically formed either of polysilicon alone or formed by first depositing a polysilicon region followed by deposition of a metal with subsequent conversion into a silicide by inducing reaction between the metal and the underlying polysilicon. Generally if the gate electrode is to be solely polysilicon, gate electrode thicknesses in the range 0.05 μm to 3 μm are employed. In contrast, if a silicide gate electrode is to be used, initially a polysilicon gate electrode region having thickness in the range 0.2 μm to 5 μm is formed. This formation of a polysilicon region is then followed using conventional photolithographic and etching techniques by the formation on a polysilicon gate of a metal layer having a thickness in the range 0.001 μm to 3 μm. Suitable metals include for example, titanium, tungsten, nickel, and cobalt. Silicide formation is induced thermally by employing a temperature in the range 500° C. to 1000° C. for a time period in the range 0.1 minute to 100 minutes. It is also possible to use tungsten silicide but in such case, thermal formation of the silicide is not employed. Instead tungsten silicide is directly deposited using a silicide thickness in the range 50 to 1000 nm. After thermal silicide formation typically the silicide region has a thickness in the range 0.001 μm to 4 μm while an underlying polysilicon region of unreacted polysilicon remains having a thickness in the range 0.001 μm to 2 μm.

The gate polysilicon (electrode) is doped to be P-type. Typically P-type carrier concentrations in the range 1×10¹⁶/cm³ to 1×10²¹/cm³ are suitable. However, it is advantageous to use a doping concentration of the order of about 5×10²⁰/cm³. Generally boron doping is employed to produce the P-type region. However, other P-type dopants such as gallium and indium are also useful. The dopant is introducible either through ion implantation or through diffusion. For ion implantation the device is masked so that underlying regions are not subject to the dopant treatment of the gate. Dopant doses in the range 1×10¹³ to 1×10¹⁸ cm⁻² are employed with implantation acceleration voltages in the range 1 keV to 30 keV.

If a gate is to be doped by a diffusion procedure it is possible to deposit the gate polysilicon region with a boron doping concentration in the range 2×10¹⁸ to 5×10²¹/cm³ using a deposition temperature in the range 400° C. to 600° C. Alternatively, a material region such as a boron doped silicon oxide glass is formed by conventional techniques such as by using a spin-on glass on the gate. The gate region having its overlying dopant source is then heated to a temperature in the range 750° C. to 1100° C. for 5 to 120 minutes. After gate formation the device is completed by conventional techniques to form, for example, drain and gate contacts. Although source contacts are also useful, in one embodiment the source is contacted by employing a backside contact using a deep silicon trench from the source region to the backside region of the silicon. The trench is typically filled with doped polysilicon to ensure suitable electrical contact. This backside source contact is described in C. S. Kim, J-W. Park, H. K. Yu, “Trenched Sinker LDMOSFET (TS-LDMOS) Structure for High Power Amplifier Application above 2 GHz”, IEEE Proceedings of the IEDM (International Electron Devices Meeting), pp. 887-890, 2001. which is hereby incorporated by reference.

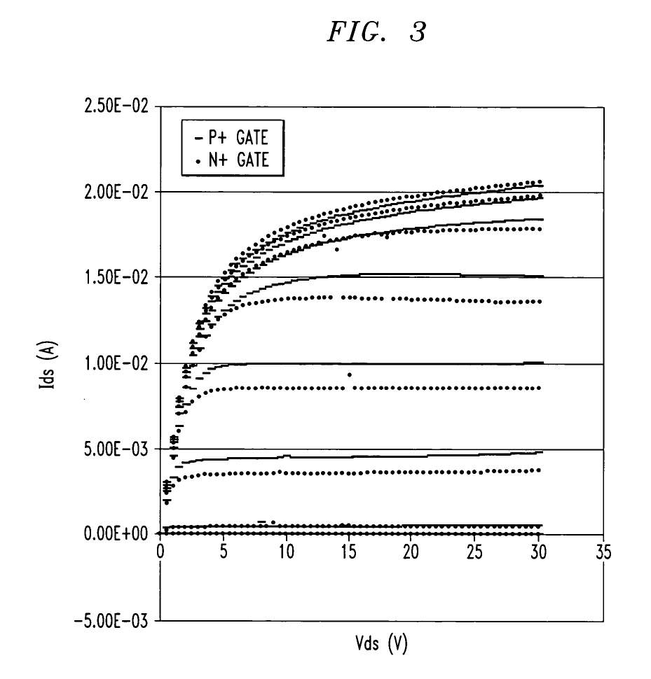

Typical electrical characteristics obtained by the use of the subject invention are shown in FIG. 3. This figure demonstrates D.C. measurement data for a P⁺ versus N⁺ gate electrode with channel dopant concentration gradient of a factor of 40 per micrometer of channel length with identical threshold voltage. The P⁺ gate shows higher transconductance in both linear and saturation regions.

1. A device formed on a substrate, said device comprising a source region in electrical communication with, a drain region through a channel that is separated from a gate electrode that controls electrical conduction in said channel by a gate dielectric wherein said channel has a lateral concentration gradient of p-type dopant that is at least a factor of 10 per micrometer of channel length, wherein said gate electrode is P-type, and wherein the distance between said drain region and channel region is in the range 0.5 to 3 μm.

2. The device of claim 1 wherein said gate electrode is P-type due to the presence of a boron, indium or gallium species.

3. The device of claim 1 wherein said gate electrode comprises a metal silicide.

4. The device of claim 3 wherein said silicide comprises titanium silicide, tungsten silicide, cobalt silicide, or nickel silicide.

5. The device of claim 1 wherein said gate comprises polysilicon.

6. The device of claim 1 wherein the dopant in said channel comprises a boron species.

7. The device of claim 1 wherein said device comprises a lateral diffusion MOS device.

8. The device of claim 7 wherein said channel comprises silicon and said gate dielectric comprises an oxide.
